(19) United States
(12) Patent Application Publication
(10) Pub. No.: US 2008/0122049 A1
(43) Pub. Date: May 29, 2008

(54) Leadframe finger design to ensure lead-locking for enhanced fatigue life of bonding wire in an overmolded package

(75) Inventors: Jie-Hua Zhao, Plano, TX (US); Vikas Gupta, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/605,553

(22) Filed: Nov. 28, 2006

(51) Int. Cl. H01L 23/495; H01L 21/56

(52) U.S. Cl. 257/669; 438/123; 257/E21.502; 257/E23.043

(57) ABSTRACT

In a method and system for fabricating a semiconductor device (200, 300 or 400), a portion of a metal sheet to form a leadframe (210, 310 or 410) having a lead finger (220, 320 or 430) is removed to form a lead finger lock (260, 360 or 460). The lead finger lock (260, 360 or 460) is disposed within a configurable distance of a wirebonding joint (240, 340 or 440) located on a surface of the lead finger (220, 320 or 430). An integrated circuit (IC) chip (290, 390 or 490) is attached to the leadframe (210, 310 or 410). A conductive pad end (232, 332 or 432) of a bond wire (230, 330 or 430) is bonded to the IC chip (290, 390 or 490) and a lead finger end (234, 334 or 434) of the bond wire is bonded to an inner end (222, 322 or 422) of the lead finger at the wirebonding joint (240, 340 or 440). The IC chip, the leadframe, the lead finger, and the wirebonding are encapsulated with a molding compound (MC) (250, 350 or 450). The lead finger lock (260, 360 or 460) that is encapsulated by the MC (250, 350 or 450) limits a relative displacement (270, 370 or 470) between the MC and the lead finger at the wirebonding joint (240, 340 or 440).

### BACKGROUND

The present invention is related in general to the field of semiconductor device packaging and more specifically to fabrication of leadframes for integrated circuit devices.

A leadframe (LF) based package is the most widely used integrated circuit (IC) package. The leadframe typically includes a chip mount pad (also referred to as a die paddle) for attaching the IC chip, and a plurality of lead fingers or conductive segments to connect to external circuits. A gap between the (“inner”) end of the lead fingers and the conductor pads on the IC surface are typically connected by thin metallic bond wires (typically made from gold, copper, aluminum, or an alloy thereof), which are individually bonded to the IC contact pads and the inner end of the lead fingers. The ends of the lead finger remote from the IC chip (referred to as “outer” ends) are electrically and mechanically connected to external circuitry. After assembly of the leadframe, a molding compound (MC) is molded over the leadframe to encapsulate the IC in a molding process. The packaging and assembly process of the semiconductor device thus includes encapsulating the IC chip, the bond wires, and at least a portion of the lead fingers by the MC.

As the semiconductor device undergoes temperature cycling, e.g., during device testing or during device usage, it is well known that thermomechanical stresses are induced at the joints or interfaces between dissimilar materials used in the fabrication of the device. The stresses are primarily induced due to a difference between the coefficients of thermal expansion (CTE) of the various materials. For example, metal used to fabricate the leadframe assembly expands or contracts differently than plastic material used as a molding compound, thereby causing delamination. These stresses, which may be repeatedly induced during hundreds or thousands of temperature cycles, tend to fatigue the joints and the interfaces, resulting in cracks, and eventual failure of the device.

Traditional techniques to reduce delamination have focused on improved formulation of the MC that provide increased adhesion to the LF surface. However, these techniques are often costly, and time consuming. Additionally, traditional tools and methods for fabricating a semiconductor package may be inadequate to ensure the integrity of selected joints such as a bond formed between a thin metallic bond wire and an inner end of a lead finger, when the device is exposed to repeated temperature cycling.

### SUMMARY

Applicants recognize that delamination between the leadframe and the MC is a frequently observed phenomenon in electronic packages. In some applications, some delamination may be allowable in packages provided the packaged devices are capable of withstanding the desired reliability tests, such as 1000 cycles of −65 degrees Celsius to 150 degrees Celsius thermal cycling test. One failure mode is the wire bond joint fatigue failure when there is delamination between the lead fingers and the MC near the wire bond joint. Applicants recognize the need for an improved lead finger lock to reduce temperature cycling induced fatigue stress on selectable joints such as a wirebonding joint, absent the disadvantages found in the prior techniques discussed above.

The foregoing need is addressed by the teachings of the present disclosure, which relates to a system and method for fabricating a semiconductor device having an improved capability to withstand stress induced by repeated temperature cycling. According to one embodiment, in a method and system for fabricating a semiconductor device, a portion of a metal sheet to form a leadframe having a lead finger is removed to form a lead finger lock. The lead finger lock is disposed within a configurable distance of a wirebonding joint located on a surface of the lead finger. An integrated circuit (IC) chip is attached to the leadframe. A conductive pad end of a wire bond is bonded to the IC chip and a lead finger end of the bond wire is bonded to an inner end of the lead finger at the wirebonding joint. The IC chip, the leadframe having multiple lead fingers, and the wirebonding joint are encapsulated with a molding compound (MC). The lead finger lock that is encapsulated by the MC limits a relative displacement between the MC and the lead finger at the wirebonding joint.

In one aspect of the disclosure, a lead finger lock is fabricated by half etching a bottom surface of the lead finger, where a cross section of the surface resembles a tooth pattern. A molding compound (MC) encapsulates the tooth pattern to limit the relative displacement between the MC and the lead finger at the wirebonding joint. In another aspect of the disclosure, a lead finger lock is fabricated by forming through holes within a configurable distance of a wirebonding joint located on a surface of the lead finger. The MC encapsulates the through holes to limit the relative displacement between the MC and the lead finger at the wirebonding joint.

Several advantages are achieved by the method and system according to the illustrative embodiments presented herein. The semiconductor device provides an improved capability to withstand stress induced as a result of repeated temperature cycling. A lead finger lock fabricated on a lead finger of the device advantageously limits relative displacement between dissimilar materials such as the molding compound encapsulating the lead finger lock and the lead finger, both of which are exposed to repeated temperature cycling. Specifically, the improved lead finger lock is advantageously disposed within a configurable distance of a wirebonding joint located on a surface of the lead finger to reduce the temperature cycling induced fatigue stress on a bond wire at or near the wirebonding joint.

### BRIEF DESCRIPTION OF THE DRAWINGS

FIG. 1A illustrates a simplified and schematic partial cross section of a leadframe and a mold compound (MC) in a package, according to prior art;

FIG. 1B illustrates a simplified and schematic partial cross section of a leadframe and an MC subjected to a temperature cycle causing delamination, according to prior art;

FIG. 2A illustrates a simplified and schematic partial cross section of a semiconductor device having a lead finger with a patterned lead finger lock, according to an embodiment;

FIG. 2B illustrates a simplified and schematic partial cross section of a lead finger with a patterned lead finger lock described with reference to FIG. 2A that is subjected to a temperature cycle, according to an embodiment;

FIG. 2C illustrates a simplified and schematic partial view of an upper surface of a lead finger with a textured side wall to form a lead finger lock, according to an embodiment.

FIG. 3A illustrates a simplified and schematic partial cross section of a semiconductor device having a lead finger with a through hole lead finger lock, according to an embodiment;

FIG. 3B illustrates a simplified and schematic top view of a lead finger with a through hole lead finger lock described with reference to FIG. 3A, according to an embodiment;

FIG. 3C illustrates a simplified and schematic partial cross section of a lead finger with a through hole lead finger lock described with reference to FIGS 3A and 3B that is subjected to a temperature cycle, according to an embodiment;

FIG. 4A illustrates a simplified and schematic partial cross section of a semiconductor device having a lead finger with a combination lead finger lock, according to an embodiment;

FIG. 4B illustrates a simplified and schematic partial cross section of a lead finger with a combination lead finger lock described with reference to FIG. 4A that is subjected to a temperature cycle, according to an embodiment; and

FIG. 5 is a flow chart illustrating a method for fabricating a semiconductor device, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) or software or a combination thereof, depending on the application requirements.

Similarly, the functionality of various mechanical elements, members, or components for forming modules, sub-assemblies and assemblies assembled in accordance with a structure for an apparatus may be implemented using various materials and coupling techniques, depending on the application requirements. Descriptive and directional terms used in the written description such as top, bottom, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

Traditional tools and methods for fabricating a semiconductor device may be inadequate to ensure the integrity of selected joints such as a bond formed between a bond wire and an inner end of a lead finger, especially when the device is exposed to repeated stresses such as temperature cycling. As a result of the repeated temperature cycling, the CTE mismatch, and inadequate adhesion between the molding compound and the lead finger, the induced stresses may cause delamination, which may eventually lead to a failure of the semiconductor device. This problem may be addressed by an improved system and method for fabricating a lead finger of a leadframe of the semiconductor device. According to an embodiment, in an improved system and method for fabricating a semiconductor device, a metal sheet is provided to form a leadframe having at least one leadfinger. A portion of a metal sheet forming at least a portion of the lead finger is removed to form a lead finger lock. The lead finger lock is disposed within a configurable distance of a wirebonding joint located on a surface of the lead finger. An integrated circuit (IC) chip is attached to the leadframe. A conductive pad end of a bond wire is bonded to the IC chip and a lead finger end of the bond wire is bonded to an inner end of the lead finger at the wirebonding joint. The IC chip, the leadframe having multiple lead fingers, and the wirebonding joints are encapsulated with a molding compound. The lead finger lock that is encapsulated by the molding compound limits a relative displacement between the molding compound and the lead finger at the wirebonding joint.

The following terminology may be useful in understanding the present disclosure. It is to be understood that the terminology described herein is for the purpose of description and should not be regarded as limiting.

Leadframe—A leadframe is a conductive support or frame structure for securely attaching an integrated circuit (IC) chip or die during packaging and assembly of a semiconductor device. The leadframe typically includes a chip mount pad (also referred to as a die paddle) for attaching the IC chip, and a plurality of lead fingers or conductive segments to connect to external circuits. A gap between the (“inner”) end of the lead fingers and the conductor pads on the IC surface are typically connected by thin metallic bond wires (typically made from gold, copper, aluminum or an alloy thereof), which are individually bonded to the IC contact pads and the lead fingers. The ends of the lead finger remote from the IC chip (referred to as “outer” ends) are electrically and mechanically connected to external circuitry. The packaging and assembly also includes encapsulating the IC chip, the bond wires, and at least a portion of the conductive segments by a polymeric or molding compound.

Semiconductor Package (or Package)—A semiconductor package provides the physical and electrical interface to at least one integrated circuit (IC) or die included in a semiconductor device for connecting the IC to external circuits. The package protects the IC from damage, contamination, and stress that result from factors such as handling, heating, and cooling.

Semiconductor Device—A semiconductor device is an electronic component that utilizes electronic properties of semiconductor materials to perform a desired function. A semiconductor device may be manufactured as a single discrete device or as one or more ICs packaged into a module.

Configuration—Describes a set up of an element, a circuit, a package, an electronic device, and similar other, and refers to a process for setting, defining, or selecting particular properties, parameters, or attributes of the device prior to its use. Some configuration attributes may be selected to have a default value. For example, a distance L between a lead finger lock and a wirebonding joint is configurable. A particular value of the distance L may be selected depending on each application.

Simulation/modeling or fatigue tests are often conducted to determine a relationship between a stress range and a number of cycles the stress may be applied before causing a fatigue induced failure in a device being tested. The type of stresses applied may include tension, compression, shear or a combination thereof. In many applications, semiconductor and packaging materials, which may be used to fabricate a semiconductor device, are subjected to various stresses caused by vibration, oscillation, temperature cycling, and similar others. Since the semiconductor and packaging material is subjected to repeated load/stress cycles (causing fatigue) in actual use or during testing, semiconductor device manufacturers are often challenged with improving fatigue life for the device, which may be defined as the total number of cycles to failure under known loading conditions. Analysis and evaluation of data obtained from simulation/modeling or fatigue testing of a semiconductor device may advantageously provide improvements such as a lead finger lock for improving the in-service life of the device.

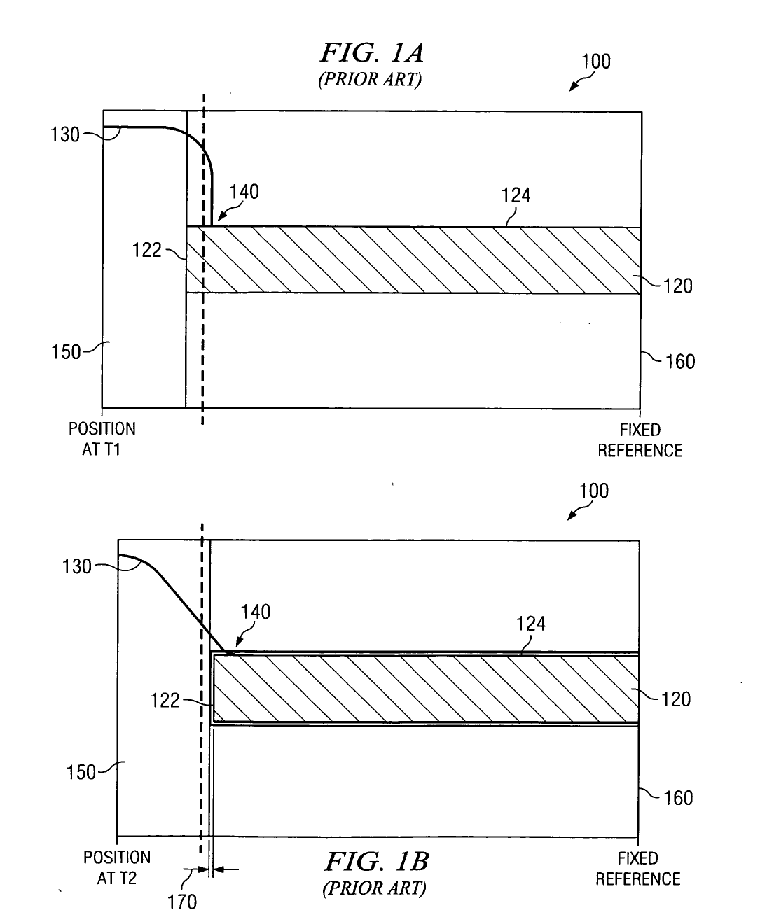

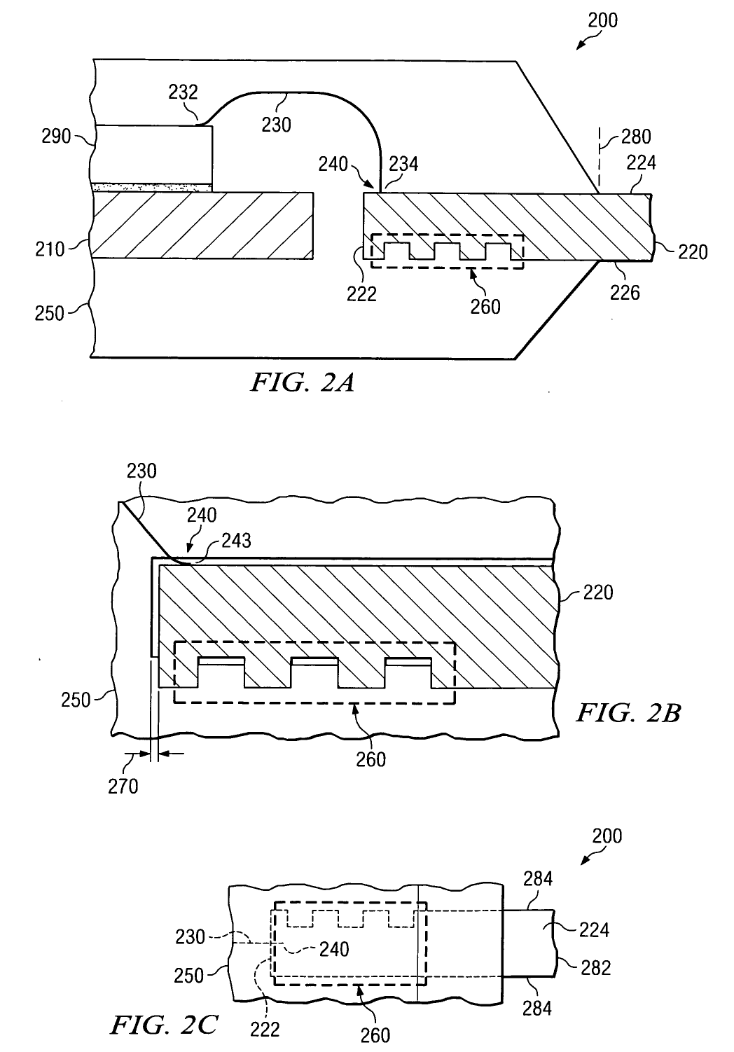

A semiconductor device having a traditional lead finger that is subjected to repeated temperature cycling is described with reference to FIGS. 1A, and 1B. A semiconductor device having a lead finger lock that provides an improved capability to withstand stress induced as a result of repeated temperature cycling is described with reference to FIGS. 2A, 2B, 2C, 3A, 3B, 3C, 4A and 4B. It is understood that although the semiconductor device is shown to have a lead finger with a lead finger lock, the semiconductor device includes multiple lead fingers, with at least one lead finger of the multiple lead fingers having a lead finger lock.

FIG. 1A illustrates a simplified and schematic partial cross section of a leadframe 100, according to prior art. In the illustration, the leadframe 100, which may be stamped from a metal sheet, includes a lead finger 120 having an inner end 122. One end of a bond wire 130 is bonded to an upper surface 124 of the lead finger 120 at a wirebonding joint 140. The other end (not shown) of the bond wire 130 is bonded to an IC (not shown). A molding compound 150 encapsulates the leadframe 100. Relative positions of the wirebonding joint 140 and an interface between the inner end 122 and the molding compound 150, which are measured relative to a fixed reference 160 are illustrated when the leadframe 100 is at a first temperature T1.

FIG. 1B illustrates a simplified and schematic partial cross section of a leadframe 100 subjected to a temperature cycle, according to prior art. In the illustration, the leadframe 100 is exposed to a temperature cycle, e.g., by decreasing the temperature to a second temperature T2 (T1>T2). Since the CTE value for the lead finger 120, e.g., 17 ppm per degree Celsius, is greater than the CTE value for the MC 150, e.g., 10 ppm per degree Celsius, each of these two materials shrink independently causing delamination. Specifically, the lead finger 120 shrinks more than the MC 150. A gap 170 is generated between the MC 150 and the inner end 122. The bond wire 130 experiences deformation and increased stress since the position of the wirebonding joint 140 is shifted due to the delamination. The position of the fixed reference 160 remains constant due to partial delamination between leadframe and the MC or other locking mechanism described in prior art.

FIG. 2A illustrates a simplified and schematic partial cross section of a semiconductor device 200 having a lead finger with a patterned lead finger lock, according to an embodiment. In the depicted embodiment, the semiconductor device 200 includes a leadframe 210 providing a base structure to mount an integrated circuit (IC) 290 using a die attach compound. The leadframe 210 includes a lead finger 220 having an inner end 222. A conductive pad end 232 of a bond wire 230 is bonded to the IC 290, and a lead finger end 234 is bonded close to the inner end 222 at a wirebonding joint 240 located on an upper surface 224. The leadframe 210 is stamped (or etched) from a metal sheet. The metal sheet is preferably made of copper or copper alloy. Other choices for the metal sheet may include brass, aluminum, an iron nickel alloy such as “Alloy 42”, and invar. The thickness of the metal sheet may be in the range from about 100 to 400 micro meters, although thinner or thicker sheets may be possible.

A bottom surface 226 of the lead finger 220 is patterned or textured to increase surface area by using a half etching or similar other material removal process. The patterned surface resembles a tooth pattern, which includes at least one indentation or notch, to form a lead finger lock 260. The lead finger lock 260 is disposed within a configurable distance of the wirebonding joint 240. As described earlier, configuration describes a set up of an element, a circuit, a package, an electronic device, and similar other, and refers to a process for setting, defining, or selecting particular properties, parameters, or attributes of the device prior to its use. Some configuration attributes may be selected to have a default value. For example, the configurable distance between a lead finger lock and a wirebonding joint is selectable depending on each application. The configurable distance may be measured along X axis (horizontal) and Y axis (vertical). In the depicted embodiment, the lead finger lock 260 and the wirebonding joint 240 are located on opposing surfaces of the lead finger 220, with a portion of the tooth pattern forming the lead finger lock 260 being located directly below the wirebonding joint 240. A molding compound (MC) 250 encapsulates the IC chip 290, the leadframe 210, the lead finger 220 including the tooth pattern of the lead finger lock 260, all sides of the lead finger lock 260, and the bond wire 230. Relative positions of the wirebonding joint 240 and an interface between the inner end 222 and the MC 250 relative to a fixed reference 280 are illustrated when the semiconductor device 200 is at a first temperature T1. In a particular embodiment, a side wall or a portion thereof of the lead finger 220 is patterned to further increase the surface area in contact with the MC. The patterned portion of the side wall resembles a tooth pattern, which includes at least one indentation or notch, to form a lead finger lock. Additional details of this embodiment are described with reference to FIG. 2C.

FIG. 2B illustrates a simplified and schematic partial cross section of a lead finger with a patterned lead finger lock described with reference to FIG. 2A that is subjected to a temperature cycle, according to an embodiment. In the illustration, the semiconductor device 200 is exposed to a temperature cycle, e.g., by decreasing the temperature to the second temperature T2 (T1>T2). Since the CTE value for the lead finger 220, e.g., 17 ppm per degree Celsius, is greater than the CTE value for the MC 250, e.g., 10 ppm per degree Celsius, each of these two materials shrink independently. Specifically, the lead finger 220 shrinks more than the MC 250. A relative displacement delta L 270 takes place between the MC 250 and the lead finger 220 at a point of interest, such as at the inner end 222. A corresponding value of the relative displacement delta L 270 at the wirebonding joint 240 is computed by using Equation 100 described below.

In an embodiment, the relative displacement delta L 270 between a first material having a CTE and a second material having a corresponding CTE is computed by Equation 100 as follows:

Delta L=(delta CTE*delta T)*Length L Equation 100

where delta CTE is a difference between the coefficient of thermal expansion (CTE) for the first material, e.g., the lead finger, and the corresponding CTE for the second material, e.g., the MC, delta T is a temperature excursion experienced by the device, and a length L is the free length of the material with the higher CTE that is capable of being displaced in response to the temperature excursion, e.g., length that is not fixed, constrained or restricted to expand or contract due to the temperature cycling. For example, a free length of the lead finger 220 is measured from the point of interest, e.g., the wirebonding joint 240 to the nearest fixed or restricted point.

As a result of the temperature cycling, an amount of stress induced in the bond wire 230 at the wirebonding joint 240 is directly related to the relative displacement delta L 270 in a manner that the larger the relative displacement, the larger the induced stress in the wirebonding joint. It is desirable that in order to limit the induced stress caused by the temperature cycling, the relative displacement delta L 270 be limited. In an embodiment, the stress induced in the bond wires 230 at the wirebonding joint 240 is limited by reducing the free length of the lead finger 220 that is capable of being displaced in response to the temperature excursion. The free length is restricted by positioning of the lead finger lock 260 as an anchor that is disposed within a configurable distance of the wirebonding joint 240. Thus, the lead finger lock 260 advantageously functions as an anchor to limit the free length. The configurable distance may be varied to adjust the free length, which limits the relative displacement delta L 270 between the MC 250 and the lead finger 220 at the wirebonding joint 240.

The one or more teeth of the lead finger lock 260 when encapsulated by the MC 250 restrict or constrain the displacement of the lead finger 220 at the wirebonding joint 240, thereby reducing the induced stress on the bond wire 230. Thus, the lead finger lock 260 forces the lead finger 220 to deform with the MC 250 to limit the relative displacement delta L 270 at the wirebonding joint 240. The particular characteristics of the tooth pattern may vary. In an embodiment, the configurable distance is adjustable to vary between 0% and less than 50% of the free length L of the lead finger 220. In this embodiment, when the configurable distance is adjusted to be equal to 0% of the free length L of the lead finger 220, the lead finger lock 260 is disposed at the inner end 222.

The relative displacement delta L 270 is advantageously less than the gap 170 described with reference to FIG. 1A due to the presence of the lead finger lock 260. Thus, the lead finger lock 260 advantageously limits the relative displacement to reduce a fatigue stress induced on the bond wire 230 at or near the wirebonding joint 240 compared to the fatigue stress induced on the bond wire 130 in the leadframe 100 without the lead finger lock.

In an embodiment, the MC 250 is an environmentally friendly or a green molding compound. The green molding compound is lead-free process compatible. In an embodiment, the MC 250 is a traditional molding compound, which may contain halogen elements. The traditional molding compound may be optionally lead-free compatible

In an embodiment, the IC chip 290 is one of one of a microprocessor, a digital signal processor, a radio frequency chip, a memory, a microcontroller, a system-on-a-chip, an analog-to-digital converter, a digital-to-analog converter, a power management device, and a combination thereof.

FIG. 2C illustrates a simplified and schematic partial view of an upper surface of a lead finger with a textured or patterned side wall to form a lead finger lock, according to an embodiment. In the depicted embodiment, a lead finger 282 has an inner end 222, and side walls 284 having a texture or a pattern. As described earlier, the patterning may be formed by an etching, stamping, or other process. A bond wire 230 having a lead finger end is bonded close to the inner end 222 at a wirebonding joint 240 located on an upper surface 224.

The side walls 284 or a portion thereof of the lead finger 282 are textured to advantageously maximize the contact surface between the lead finger 282 and the MC 250. The side walls 284 of the lead finger 282 are patterned resembling a tooth pattern, which includes at least one indentation or notch, to form a lead finger lock 260. The particular characteristics of the tooth pattern may vary to maximize the contact surface. That is, in an exemplary, non-depicted embodiment, alternative patterns such as triangular, semi-circular, for forming the lead finger lock 260 are contemplated. The alternative patterns may be formed on one of the side walls 282 or may be formed on both the side walls 282. It is also understood, that the lead finger lock 260 features described with reference to FIGS. 2A and 2B may be combined with the lead finger lock 260 features described with reference to FIG. 2C. That is, a lead finger lock having pattered side walls and also having patterned bottom surface may be provided to further reduce the induced stress at the wirebonding joint 240.

The lead finger lock 260 is disposed within a configurable distance of the wirebonding joint 240. A molding compound (MC) 250 encapsulates the lead finger 282 including the tooth pattern of the lead finger lock 260, all sides of the lead finger lock 260, and the bond wire 230 to form a package for the semiconductor device. It is understood that, although not shown, the MC 250 also encapsulates other lead fingers having a corresponding lead finger lock. As described earlier, a semiconductor package provides the physical and electrical interface to at least one integrated circuit (IC) or die for connecting the IC to external circuits. The package protects the IC from damage, contamination, and stress that result from factors such as handling, heating, and cooling

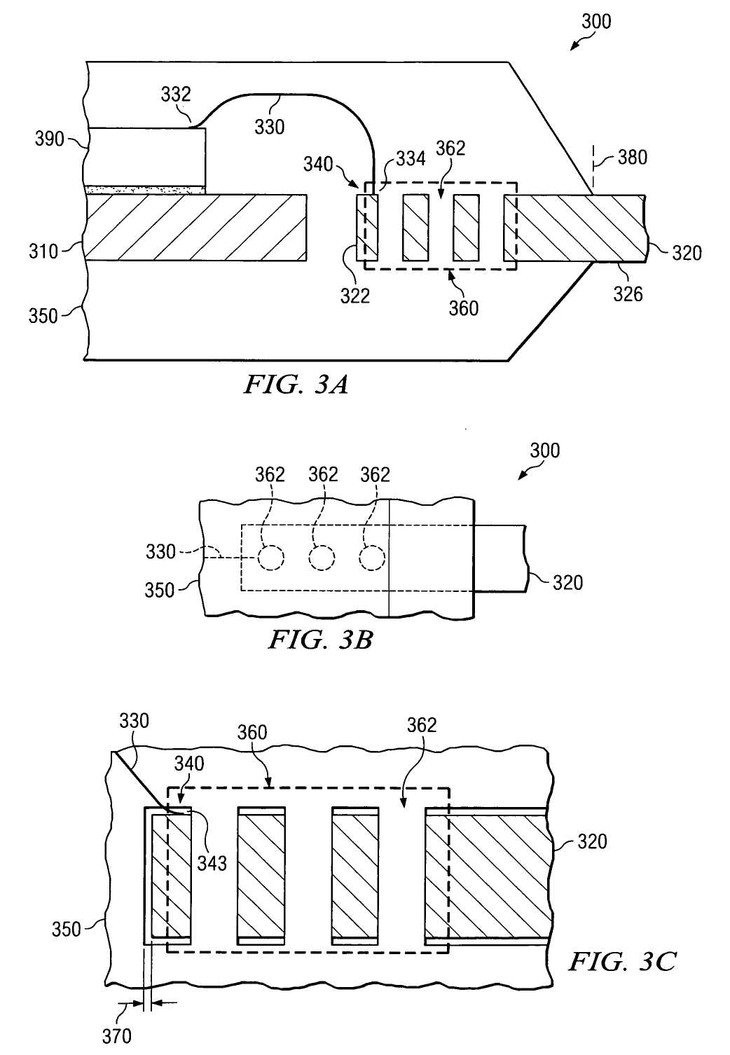

FIG. 3A illustrates a simplified and schematic partial cross section of a semiconductor device 300 having a lead finger with a through holed lead finger lock, according to an embodiment. FIG. 3B illustrates a simplified and schematic top view of a lead finger with a through holed lead finger lock described with reference to FIG. 3A, according to an embodiment. In an embodiment, the semiconductor device 300 is the same as the semiconductor device 200 described with reference to FIGS. 2A and 2B except for the through holed lead finger lock 360. Referring to FIGS. 3A and 3B, the semiconductor device 300 includes a leadframe 310 providing a base structure to mount an integrated circuit (IC) 390 using a die attach compound. The leadframe 310 includes a lead finger 320 having an inner end 322. A conductive pad end 332 of a bond wire 330 is bonded to the IC 390, and a lead finger end 334 is bonded close to the inner end 322 at a wirebonding joint 340.

The lead finger 320 has through holes 362 to form a lead finger lock 360. The lead finger lock 360 is disposed within a configurable distance of the wirebonding joint 340. A molding compound (MC) 350 encapsulates the IC chip 390, the leadframe 310, the lead finger 320 including the through holes 362 of the lead finger lock 360 (that is, all sides and surfaces of the lead finger lock 360), and the bond wire 330. Relative positions of the wirebonding joint 340 and an interface between the inner end 322 and the MC 350 relative to a fixed reference 380 are illustrated when the semiconductor device 300 is at a first temperature T1.

FIG. 3C illustrates a simplified and schematic partial cross section of a lead finger with a through holed lead finger lock described with reference to FIGS. 3A and 3B that is subjected to a temperature cycle, according to an embodiment. In an embodiment, the semiconductor device 300 is exposed to a temperature cycle, e.g., by decreasing the temperature to the second temperature T2 (T1>T2). Since the CTE value for the lead finger 320, e.g., 17 ppm per degree Celsius, is greater than the CTE value for the MC 350, e.g., 10 ppm per degree Celsius, each of these two materials shrink independently. Specifically, the lead finger 320 shrinks more than the MC 350. A relative displacement delta L 370 takes place between the MC 350 and the lead finger 320 at a point of interest, such as the inner end 322. A corresponding value of the relative displacement delta L 370 at the wirebonding joint 340 is computed by using Equation 100 described earlier with reference to FIG. 2B.

As a result of the temperature cycling, an amount of stress induced in the bond wire 330 at the wirebonding joint 340 is proportional to the relative displacement delta L 370. It is desirable that in order to limit the induced stress caused by the temperature cycling, the relative displacement delta L 370 be limited. In an embodiment, the stress induced in the bond wire 330 at the wirebonding joint 340 is limited by reducing the free length of the lead finger 320 that is capable of being displaced in response to the temperature excursion. The free length is restricted by positioning of the lead finger lock 360 as an anchor that is disposed within a configurable distance of the wirebonding joint 340. The lead finger lock 360 advantageously functions as an anchor to limit the free length. The configurable distance may be varied to adjust the free length, which limits the relative displacement delta L 370 between the MC 350 and the lead finger 320 at the wirebonding joint 340.

The one or more through holes 362 of the lead finger lock 360 when encapsulated by the MC 350 restrict or constrain the displacement of the lead finger 320 at the wirebonding joint 340, thereby reducing the induced stress on the bond wire 330. Thus, the lead finger lock 360 forces the lead finger 320 to deform with the MC 350 to limit the relative displacement delta L 370 at the wirebonding joint 340. The particular characteristics of the through holes 362 such as size, shape (e.g., cylindrical, conical, irregular, and similar others) orientation (e.g., vertical, at an angle, and similar others) of the holes may vary. The through holes 362 may be formed as fully etched vias. In an embodiment, the configurable distance is adjustable to vary between 0% and less than 50% of the free length L of the lead finger 320. In this embodiment, when the configurable distance is adjusted to be equal to 0% of the free length L of the lead finger 320, the lead finger lock 660 is disposed at the inner end 322.

The relative displacement delta L 370 is advantageously less than the gap 170 described with reference to FIG. 1A due to the presence of the lead finger lock 360. Thus, the lead finger lock 360 advantageously limits the relative displacement to reduce a fatigue stress induced on the bond wire 330 at the wirebonding joint 340 compared to the fatigue stress induced on the bond wire 130 in the leadframe 100 without the lead finger lock.

In an embodiment, the MC 350 is the same as the MC 250, and the IC chip 370 is the same as the IC chip 270 described with reference to FIGS. 2A, 2B, and 2C.

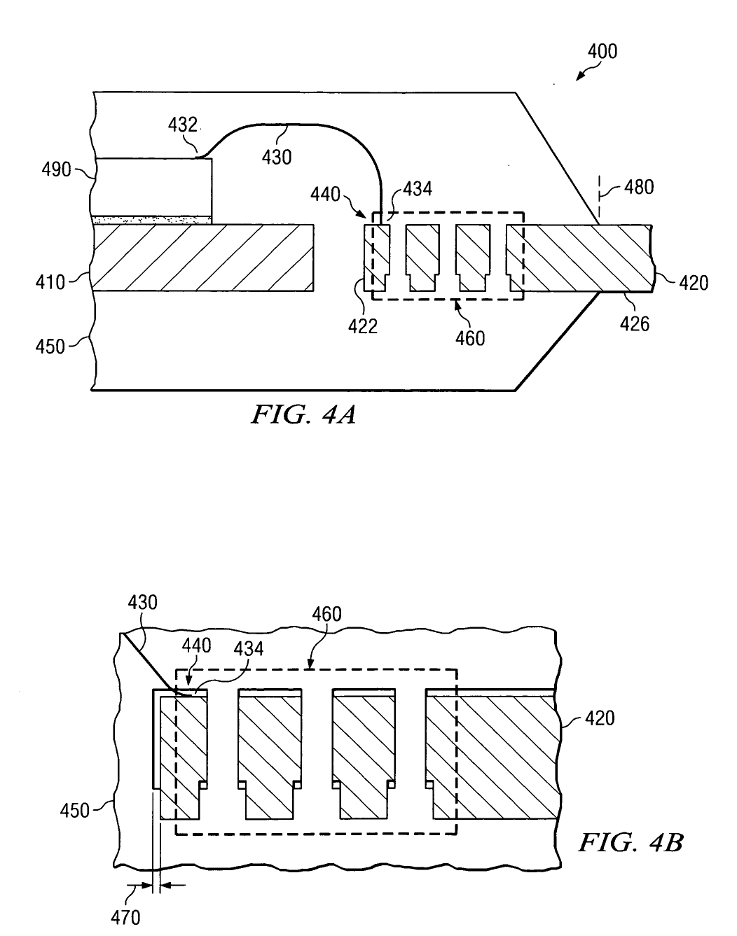

FIG. 4A illustrates a simplified and schematic partial cross section of a semiconductor device 400 having a lead finger with a combination lead finger lock, according to an embodiment. In an embodiment, the semiconductor device 400 is the same as the semiconductor device 200 described with reference to FIGS. 2A, 2B and 2C, and the semiconductor device 300 described with reference to FIGS. 3A and 3B, except for the combination lead finger lock 460. In the depicted embodiment, the semiconductor device 400 includes a leadframe 410 providing a base structure to mount an integrated circuit (IC) 490 using a die attach compound. The leadframe 410 includes a lead finger 420 having an inner end 422. A conductive pad end 432 of a bond wire 430 is bonded to the IC 490, and a lead finger end 434 is bonded to the inner end 422 at a wirebonding joint 440.

The lead finger 420 has combined features of the lead finger lock 260 described with reference to FIGS. 2A and 2B, and the lead finger lock 360 described with reference FIGS. 3A, 3B and 3C to form the combined lead finger lock 460. A bottom surface 426 of the lead finger 420 is patterned resembling a tooth pattern having at least one indentation or notch, and a portion of the lead finger 420 includes through holes 462 to form the combined lead finger lock 460. The combined lead finger lock 460 is disposed within a configurable distance of the wirebonding joint 440. A molding compound (MC) 450 encapsulates the IC chip 490, the leadframe 410, the lead finger 420 including the combined lead finger lock 460, all sides and surfaces of the lead finger lock 460, and the bond wire 430. Although not shown, multiple lead fingers, with at least one of the lead fingers having a corresponding combined lead finger lock are also encapsulated by the MC 450. Relative positions of the wirebonding joint 440 and an interface between the inner end 422 and the MC 450 relative to a fixed reference 480 are illustrated when the semiconductor device 400 is at a first temperature T1.

FIG. 4B illustrates a simplified and schematic partial cross section of a lead finger with a combination lead finger lock described with reference to FIG. 4A that is subjected to a temperature cycle, according to an embodiment. In the illustration, the semiconductor device 400 is exposed to a temperature cycle, e.g., by decreasing the temperature to the second temperature T2 (T1>T2). Since the CTE value for the lead finger 420, e.g., 17 ppm per degree Celsius, is greater than the CTE value for the MC 450, e.g., 10 ppm per degree Celsius, each of these two materials shrink independently. Specifically, the lead finger 420 shrinks more than the MC 450. A relative displacement delta L 470 takes place between the MC 450 and the lead finger 420 at the point of interest, such as the inner end 422. A corresponding value of the relative displacement delta L 470 at the wirebonding joint 240 is computed by using Equation 100 described earlier with reference to FIG. 2B.

In an embodiment, the operation of the combination lead finger lock 460 is the same as the operation of the lead finger lock 260 described with reference to FIG. 2A and the lead finger lock 360 described with reference FIG. 3A.

The relative displacement delta L 470 is advantageously less than the gap 170 described with reference to FIG. 1A due to the presence of the combination lead finger lock 460. Thus, the combination lead finger lock 460 advantageously limits the relative displacement to reduce a fatigue stress induced on the bond wire 430 at the wirebonding joint 440 compared to the fatigue stress induced on the bond wire 130 in the leadframe 100 without the lead finger lock.

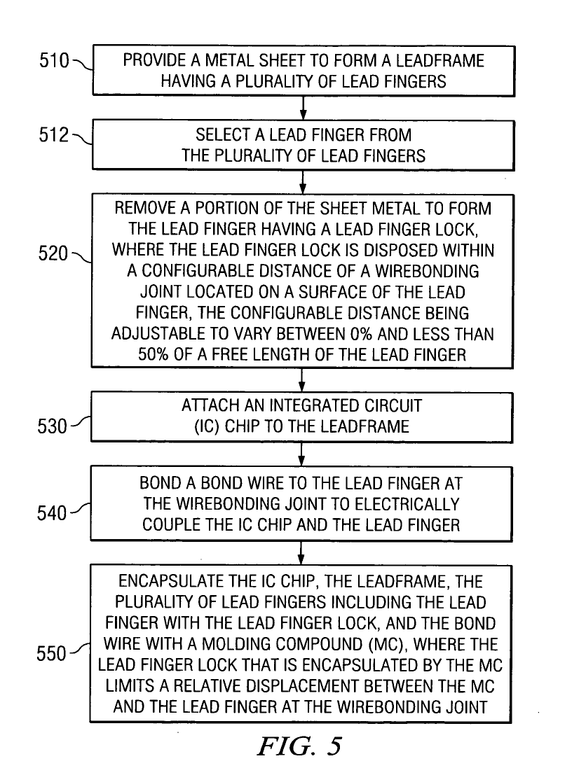

FIG. 5 is a flow chart illustrating a method for fabricating a semiconductor device, according to an embodiment. In a particular embodiment, the method is used to fabricate the semiconductor devices 200, 300, and 400 described with reference to FIGS. 2A, 2B, 2C, 3A, 3B, 3C, 4A, and 4B. At step 510, a metal sheet is provided to form a leadframe having a plurality of lead fingers. At step 512, a lead finger is selected from the plurality of lead fingers. At step 520, a portion of the sheet metal is removed, e.g., by stamping or etching, to form the lead finger having a lead finger lock, where the lead finger lock is disposed within a configurable distance of a wirebonding joint located on a surface of the lead finger. In an embodiment, the configurable distance is adjustable to vary between 0% and less than 50% of the free length L of the lead finger. Thus, at least one of the lead fingers of the plurality of lead fingers, e.g., the selected one in step 512, has a lead finger lock. At step 530, an integrated circuit (IC) chip is attached to the leadframe. At step 540, a bond wire is bonded to the lead finger at the wirebonding joint to electrically couple the IC chip and the lead finger. At step 550, the IC chip, the leadframe, the multiple lead fingers with at least one lead finger having the lead finger lock, all sides and surfaces of the lead finger lock, the bond wire and the wirebonding joint is encapsulated with a molding compound (MC). The lead finger lock that is encapsulated by the MC limits a relative displacement between the MC and the lead finger at the wirebonding joint.

Various steps described above with reference to FIG. 5 may be added, omitted, combined, altered, or performed in different orders. For example, the step 520 may be split into a first step to prepare a stamp pattern or etch mask for use in a stamping or an etching process, and a second step to perform the stamping or etching for the removal of a portion of the sheet metal.

Several advantages are achieved by the method and system according to the illustrative embodiments presented herein. The semiconductor device provides an improved capability to withstand stress induced as a result of repeated temperature cycling. A lead finger lock fabricated on a lead finger of the device advantageously limits relative displacement between dissimilar materials such as the MC encapsulating the lead finger lock and the lead finger, both of which are exposed to repeated temperature cycling. Specifically, the improved lead finger lock is advantageously disposed within a configurable distance of a wirebonding joint located on a surface of the lead finger to reduce the temperature cycling induced fatigue stress on a wirebonding joint at the wirebonding joint.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of reducing fatigue stress at a selectable joint or interface such as a wirebonding joint, those of ordinary skill in the art will appreciate that the processes disclosed are capable of being used for limiting relative displacement between dissimilar materials that may be exposed to repeated stresses such as temperature cycling. As another example, while certain aspects of the present disclosure have been described using a leadframe having an exemplary lead finger with a lead finger lock, those of ordinary skill in the art will appreciate that the processes disclosed are capable of being used for fabricating a leadframe having multiple lead fingers, each having a corresponding lead finger lock.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A semiconductor device comprising:
an integrated circuit (IC) chip;
a bond wire having a conductive pad end and a lead finger end, wherein the conductive pad end is bonded to the IC chip;
a lead finger having an inner end, wherein the lead finger end is bonded to the inner end at a wirebonding joint;
a lead finger lock disposed within a configurable distance of the inner end, wherein the configurable distance is adjustable to vary between 0% and less than 50% of a free length of the lead finger; and
a molding compound (MC) to encapsulate the IC chip, the bond wire, the inner end of the lead finger and the lead finger lock, wherein the lead finger lock limits a relative displacement between the MC and the lead finger at the wirebonding joint.

2. The device of claim 1, wherein the relative displacement is computed as a product of a difference between a coefficient of thermal expansion (CTE) for the lead finger and a CTE for the MC, a temperature excursion experienced by the device, and the free length.

3. The device of claim 2, wherein the free length is capable of being displaced in response to the temperature excursion.

4. The device of claim 2, wherein the free length of the lead finger is fixed by an anchor, wherein the anchor restricts a displacement of the lead finger in response to the temperature excursion, wherein the anchor is the lead finger lock.

5. The device of claim 1, wherein the MC is one of a green molding compound and a traditional molding compound, wherein the green molding compound is lead-free process compatible and the traditional molding compound is optionally lead-free process compatible.

6. The device of claim 1, wherein the lead finger lock comprises a patterned side wall of the lead finger, wherein the patterned side wall is formed within the configurable distance.

7. The device of claim 6, wherein the patterned side wall resembles a tooth pattern containing at least one indentation, wherein the MC encapsulates the tooth pattern to limit the relative displacement.

8. The device of claim 1, wherein the lead finger lock comprises the lead finger that is half etched on a surface opposing the wirebonding joint, the half etched surface resembling a tooth pattern containing at least one indentation, wherein the MC encapsulates the tooth pattern to limit the relative displacement.

9. The device of claim 1, wherein the lead finger lock comprises the lead finger having through holes, wherein the MC encapsulates the through holes to limit the relative displacement.

10. The device of claim 1, wherein the lead finger lock comprises the lead finger that is half etched on a surface opposing the wirebonding joint, the half etched surface resembling a tooth pattern, wherein the lead finger includes through holes.

11. The device of claim 10, wherein the MC encapsulates the tooth pattern to limit the relative displacement, wherein the MC also encapsulates the through holes to further limit the relative displacement.

12. The device of claim 1, wherein the lead finger lock limits the relative displacement to reduce a fatigue stress induced on the bond wire at the wirebonding joint compared to the fatigue stress induced on the bond wire in a device without the lead finger lock.

13. The device of claim 1, wherein the IC chip is one of one of a microprocessor, a digital signal processor, a radio frequency chip, a memory, a microcontroller, a system-on-a-chip, an analog-to-digital converter, a digital-to-analog converter, a power management device, and a combination thereof.

14. A method for fabricating a semiconductor device, the method comprising:
providing a metal sheet to form a leadframe having a plurality of lead fingers;
selecting a lead finger of the plurality of lead fingers;
removing a portion of the sheet metal forming the lead finger to form a lead finger lock, wherein the lead finger lock is disposed within a configurable distance of a wirebonding joint located on a surface of the lead finger, wherein the configurable distance is adjustable to vary between 0% and less than 50% of a free length of the lead finger;
attaching an integrated circuit (IC) chip to the leadframe;
bonding a bond wire to the lead finger at the wirebonding joint, thereby electrically coupling the IC chip and the lead finger; and
encapsulating the IC chip, the leadframe, the plurality of lead fingers, and the bond wire with a molding compound (MC), wherein the lead finger lock that is encapsulated by the MC limits a relative displacement between the MC and the lead finger at the wirebonding joint.

15. The method of claim 14, wherein removing the portion of the sheet metal includes:
patterning a surface of the lead finger opposing the wirebonding joint, wherein the surface that is patterned resembles a tooth pattern, wherein the MC encapsulates the tooth pattern to limit the relative displacement.

16. The method of claim 14, wherein removing the portion of the sheet metal includes:
providing through holes in the metal sheet of the lead finger, wherein the MC encapsulates the through holes to limit the relative displacement.

17. The method of claim 14, wherein the relative displacement is computed as a product of a difference between a coefficient of thermal expansion (CTE) for the lead finger and a corresponding CTE for the MC, a temperature excursion experienced by the device, and the free length.

18. The method of claim 17, wherein the free length is capable of being displaced in response to the temperature excursion.

19. The method of claim 14, wherein removing the portion of the sheet metal includes:
patterning a side wall of the lead finger, wherein the patterned side wall is formed within the configurable distance, wherein the patterned side wall resembles a tooth pattern having at least one indentation, wherein the MC encapsulates the tooth pattern to limit the relative displacement.

20. The method of claim 14, wherein the IC chip is one of one of a microprocessor, a digital signal processor, a radio frequency chip, a memory, a microcontroller, a system-on-a-chip, an analog-to-digital converter, a digital-to-analog converter, a power management device, and a combination thereof.
